(19) United States
(12) Patent Application Publication
(10) Pub. No.: US 2014/0038398 A1
(43) Pub. Date: Feb. 6, 2014

(54) SUBSTRATE TREATING METHODS AND APPARATUSES EMPLOYING THE SAME

(71) Applicant: Samsung Electronics Co., Ltd., Suwon-si (KR)

(72) Inventor: Jung Shik Heo, Bupyeong-gu (KR)

(73) Assignee: Samsung Electronics Co., Ltd., Suwon-si (KR)

(21) Appl. No.: 13/950,856

(22) Filed: Jul. 25, 2013

(30) Foreign Application Priority Data
Aug. 3, 2012 (KR) 10-2012-0085398

(51) Int. Cl. H01L 21/02

(52) U.S. Cl. CPC H01L 21/02068
USPC 438/585; 510/175; 438/753

(57) ABSTRACT

In a method of treating a substrate according to the inventive concept, the substrate is treated using a buffer solution including carbon dioxide (CO₂) water in combination with an alkaline solution.

### CROSS-REFERENCE TO RELATED APPLICATIONS

This U.S. non-provisional patent application claims priority under 35 U.S.C. §119 to Korean Patent Application No. 10-2012-0085398, filed on Aug. 3, 2012, the entirety of which is incorporated by reference herein.

### FIELD OF THE INVENTION

The inventive concept relates to methods for treating a substrate and apparatuses used to treat substrates according to the methods described herein.

### BACKGROUND

Semiconductor devices have become increasingly fast. Additionally, semiconductor devices have become highly integrated, such that sizes of patterns in the semiconductor devices have become finer. Thus, a turn-on current of a transistor may be reduced, so that an operation speed of the transistor is also reduced. Additionally, a contact resistance between a drain region (or a source region) and a contact structure may increase such that the operation speed of the transistor may be reduced. The operation speed of semiconductor devices may be reduced by the factors described above. Thus, it is desirable to reduce a resistance of a gate for improving the operation speed of a highly integrated transistor.

### SUMMARY

Embodiments of the inventive concept may provide methods of treating a substrate capable of effectively removing small-sized particles.

Embodiments of the inventive concept may also provide substrate treating apparatuses capable of effectively removing small-sized particles.

In one aspect, a method of treating a substrate may include providing a buffer solution including CO₂ water and an alkaline solution mixed with each other to treat the substrate.

In an embodiment, the alkaline solution may be formed by electrolyzing water. Electrolyzing the water may include separating hydrogen from the water.

In an embodiment, the alkaline solution may include NH₄OH or tetramethyl ammonium hydroxide (TMAH).

In an embodiment, the buffer solution may not substantially include oxygenated water.

In an embodiment, the substrate may include a metal layer formed thereon.

In an embodiment, treating the substrate may include removing particles from the substrate.

In another aspect, a method of forming a semiconductor device may include forming a metal layer on a substrate and treating the substrate using a buffer solution including CO₂ water and an alkaline solution which are mixed with each other.

In an embodiment, the method may further include forming a gate insulating layer on the substrate and forming a metal gate including the metal layer on the gate insulating layer. The gate insulating layer may include a refractory metal oxide layer, a refractory metal silicon oxide layer, and/or a refractory metal silicon oxynitride layer.

In still another aspect, a substrate treating apparatus may include a first cleaning solution supply unit providing an alkaline solution; a second cleaning solution supply unit dissolving carbon dioxide (CO₂) into water to form CO₂ water; a cleaning solution mixing unit connected to the first and second cleaning solution supply units, the cleaning solution mixing unit mixing the alkaline solution with the CO₂ water to form a buffer solution; and a spray unit spraying the buffer solution on a substrate.

In an embodiment, the first cleaning solution supply unit may electrolyze water.

### BRIEF DESCRIPTION OF THE DRAWINGS

The inventive concept will become more apparent in view of the attached drawings and accompanying detailed description.

FIG. 1 is a schematic diagram illustrating a substrate treating apparatus according to exemplary embodiments of the inventive concept;

FIG. 2 is a schematic diagram illustrating an example of a spray unit according to exemplary embodiments of the inventive concept;

FIG. 3 is a schematic diagram illustrating another example of a spray unit according to exemplary embodiments of the inventive concept;

FIG. 4 is a graph illustrating a cleaning result according to exemplary embodiments of the inventive concept;

FIG. 5 is a graph illustrating a cleaning result according to exemplary embodiments of the inventive concept;

FIG. 6 is a plan view illustrating an example of a layout of a semiconductor device;

FIGS. 7 to 11, 12A, and 13 to 15 are cross-sectional views taken along lines I-I′ and II-II′ of FIG. 6 to illustrate a method of forming a semiconductor device according to some embodiments of the inventive concept;

FIG. 12B is an enlarged view of a portion ‘A’ of FIG. 12A;

FIGS. 16 to 22 are cross-sectional views illustrating a method of forming a semiconductor device according to other embodiments of the inventive concept;

FIGS. 23 and 24 are cross-sectional views illustrating a method of forming a semiconductor device according to still other embodiments of the inventive concept;

FIG. 25 is a schematic block diagram illustrating an example of electronic devices including semiconductor devices formed according to exemplary embodiments of the inventive concept;

FIG. 26 is a schematic block diagram illustrating an example of memory cards including semiconductor devices formed according to exemplary embodiments of the inventive concept; and

FIG. 27 is a schematic block diagram illustrating an example of information processing systems including semiconductor devices formed according to exemplary embodiments of the inventive concept.

### DETAILED DESCRIPTION OF THE EMBODIMENTS

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments of inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted regions. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments of inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein. In addition, a phrase “at least one” is used herein to indicate that one or more respective components may be used in any combination.

The term “substantially not contain or include” may be used herein to indicate that the content may be at most very small as understood by one of ordinary skill in the art.

A semiconductor device to be described herein may be a memory device, a non-memory device, and/or a driving device for a memory or non-memory device.

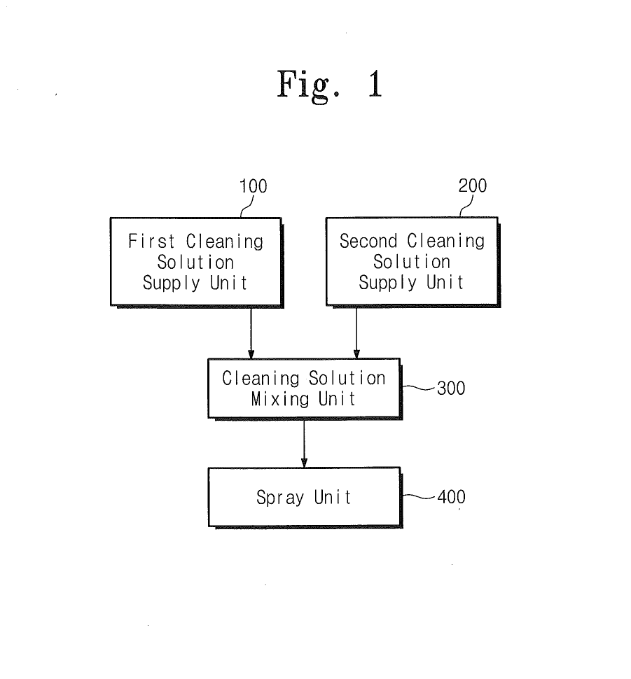

FIG. 1 is a schematic diagram illustrating a substrate treating apparatus according to exemplary embodiments of the inventive concept. Referring to FIG. 1, a substrate treating apparatus according to the inventive concept includes a first cleaning solution supply unit 100 providing an alkaline solution; a second cleaning solution supply unit 200 providing CO₂ water including water and carbon dioxide (CO₂(g)) dissolved in the water; a cleaning solution mixing unit 300 connected to the first and second cleaning solution supply units 100 and 200, the cleaning solution mixing unit 300 mixing the CO₂ water with the alkaline solution to form a buffer solution; and a spray unit 400 spraying the buffer solution on a substrate.

The substrate treating apparatus according to the inventive concept provides the buffer solution including the CO₂ water and the alkaline solution mixed with each other to the substrate to remove particles disposed on the substrate.

The first cleaning solution supply unit 100 provides the alkaline solution. The alkaline solution may be formed by electrolyzing water. The electrolyzed water may further include NH₄OH or tetramethyl ammonium hydroxide (TMAH). Electrolyzing the water includes a process for separating hydrogen from the water. Alternatively, the alkaline solution may be a solution including NH₄OH or TMAH without electrolysis of water. The alkaline solution may reduce a zeta potential of the particles, so that the particles may be restrained from being re-adsorbed on the substrate. A concentration of NH₄OH or TMAH in the alkaline solution may have a range of about hundreds ppm (parts per million) to several %. In particular, the concentration of NH₄OH or TMAH may have a range of about hundreds ppm to 0.1% in the alkaline solution.

The second cleaning supply unit 200 provides the CO₂ water. Carbon dioxide (CO₂(g)) may dissolve in water to form the CO₂ water. A portion of the carbon dioxide (CO₂(g)) dissolves in the water, such that the portion of the carbon dioxide (CO₂(g)) is removed and carbonate (e.g., CO₃²⁻, and/or HCO₃₋) is generated. This transformation is dependent on the amount of hydroxyl groups (OH⁻). The carbon dioxide (CO₂(g)) may not completely dissolve in the water, such that most of the carbon dioxide (CO₂(g)) may exist in a gas phase.

The cleaning solution mixing unit 300 mixes the CO₂ water with the alkaline solution to form the buffer solution. Since the alkaline solution generated by the electrolysis of water includes a greater quantity of hydroxyl groups (OH⁻), the carbon dioxide (CO₂(g)) of the CO₂ water may effectively dissolve in the alkaline solution. In particular, NH₄OH or TMAH additionally contained in the alkaline solution may be combined with the carbon dioxide (CO₂(g)) to generate NH₄HCO₃. The buffer solution does not substantially include hydrogen peroxide (H₂O₂).

The buffer solution sprayed by the spray unit 400 includes carbon dioxide (CO₂(g)) supersaturated in water. The carbon dioxide (CO₂(g)) supersaturated in the water may be adhered to surfaces of the particles on the substrate. The carbon dioxide (CO₂(g)) supersaturated in the water may be combined with the hydroxyl groups (OH⁻) to generate the carbonate. In this process, a volume of the water around the particle is partially reduced by about 1/1000 or less of an original volume of the water. In other words, a portion of a region around the particle becomes a vacuum state in a moment. This pressure variation makes an impact on the particles, such that the particles can be removed.

Generally, a cleaning solution (SC1) containing ammonium hydroxide (HN₄OH) and hydrogen peroxide (H₂O₂) is used for removing particles adhered to a substrate. However, the hydrogen peroxide (H₂O₂) etches a metal layer (particularly, a metal nitride layer such as a titanium nitride layer or a tantalum nitride layer). The metal nitride layer is widely used as a metal gate and/or a diffusion preventing layer. Thus, SC1 is generally not suitable for cleaning a substrate including the metal nitride layer.

The cleaning method according to the inventive concept is suitable for cleaning the substrate including a metal layer and/or the metal nitride layer. In other words, the cleaning method according to the inventive concept may be effective in cleaning the surface of the substrate with minimal, if any, damage of circuit patterns on the substrate. Particularly, as patterns of semiconductor devices become finer, it is increasingly desirable to remove small sized particles (e.g., particles of several tens nm). The small sized particles may be removed more readily by the cleaning method according to the inventive concept.

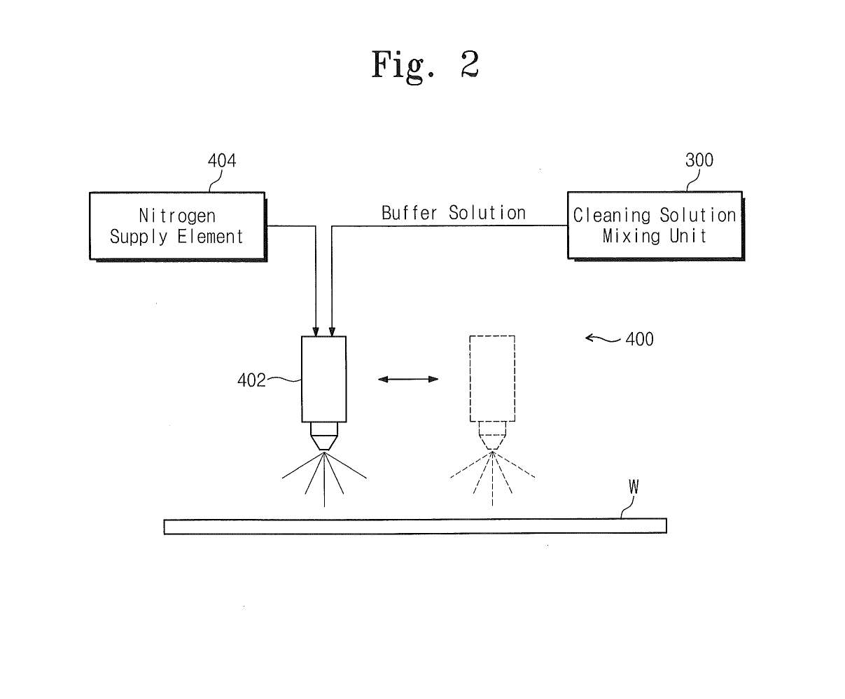

FIG. 2 is a schematic diagram illustrating an example of a spray unit according to exemplary embodiments of the inventive concept. Referring to FIG. 2, the spray unit 400 provides the buffer solution to a spray nozzle 402. The movable spray nozzle 402 sprays the buffer solution on a substrate W. Pressurized nitrogen may be provided into the spray nozzle 402 to spray the buffer solution. The pressurized nitrogen is provided by a nitrogen supply element 404.

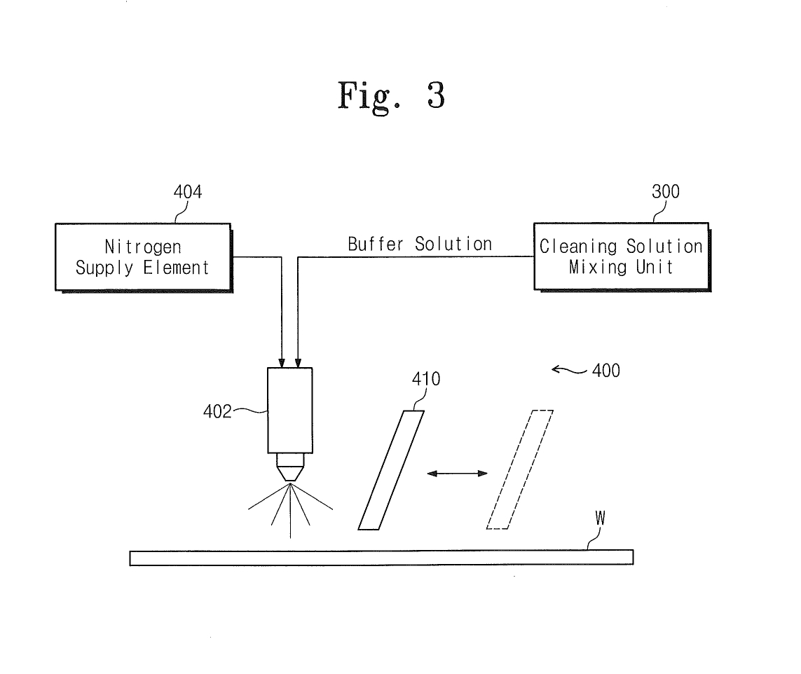

FIG. 3 is a schematic diagram illustrating another example of a spray unit according to exemplary embodiments of the inventive concept. Referring to FIG. 3, a spray unit 400 may further include a sonic unit 410. The buffer solution provided from the spray nozzle 402 is sprayed on the substrate W and the sonic unit 410 adjacent to a surface of the substrate W vibrates at the same time. The vibration generated by the sonic unit 410 is transmitted to the buffer solution, such that the particles may be more effectively removed from the substrate W.

In an embodiment, a concentration of NH₄OH or TMAH may be increased in the buffer solution. For example, the concentration of NH₄OH or TMAH in the buffer solution may have a range of about 2% to about 30%. NH₄OH or TMAH may effectively etch a silicon or poly-silicon layer. Thus, the buffer solution additionally including a higher concentration of NH₄OH or TMAH can effectively etch the silicon or poly-silicon layer and can also more effectively remove particles. In another embodiment, the buffer solution according to the inventive concept and an etching solution including NH₄OH or TMAH may be alternately used. The etching solution including NH₄OH or TMAH may etch the silicon or poly-silicon layer, and the buffer solution according to the inventive concept may remove particles caused by etching.

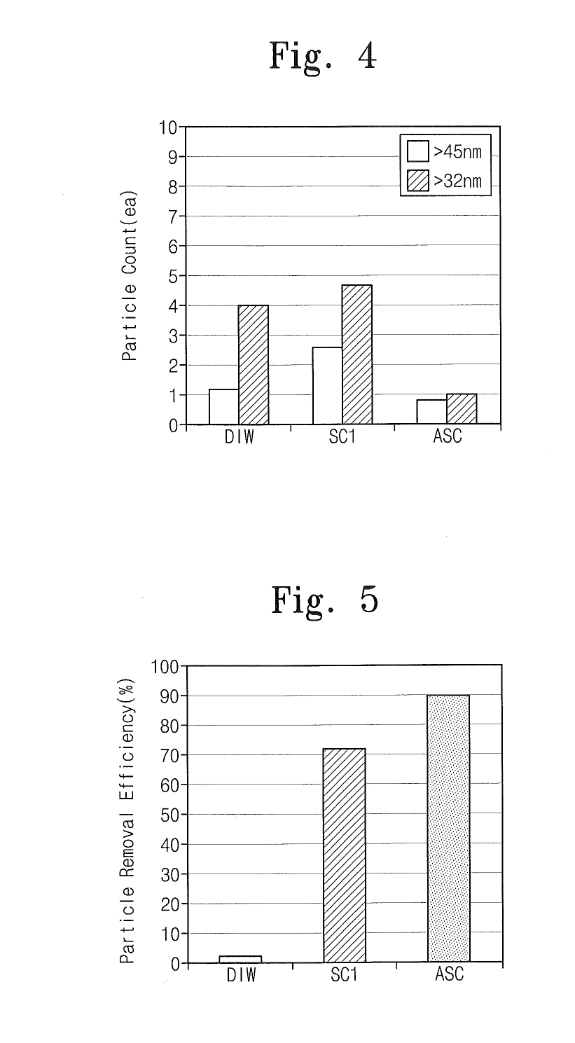

FIGS. 4 and 5 are graphs illustrating cleaning results according to exemplary embodiments of the inventive concept. FIG. 4 illustrates cleaning results of test substrates which were cleaned using deionized water (DIW), the SC1, and the buffer solution (ASC) according to the inventive concept under the same conditions. Particles of several tens nm are more effectively removed by the cleaning method using the buffer solution (ASC) according to the inventive concept than by other cleaning methods using the deionized water (DIW) and the SC1. FIG. 5 illustrates particle removal efficiency (PRE). Baked polystyrene latex (PSL) particles were dispersed on test substrates. The number of the PSL particles was equal to or greater than about 10,000 (sizes of the PSL particles >45 nm) on each of the test substrates. The particles of several tens nm are more effectively removed by the cleaning method using the buffer solution according to the inventive concept than by other cleaning methods. In particular, the PRE of the cleaning method using the buffer solution of the inventive concept was 34% higher than the PRE of the cleaning method using the SC1. On the other hand, unlike the inventive concept, when the alkaline solution and the CO₂ water were sequentially provided, a PRE in this case was a level of the PRE of the cleaning method using the deionized water (DIW).

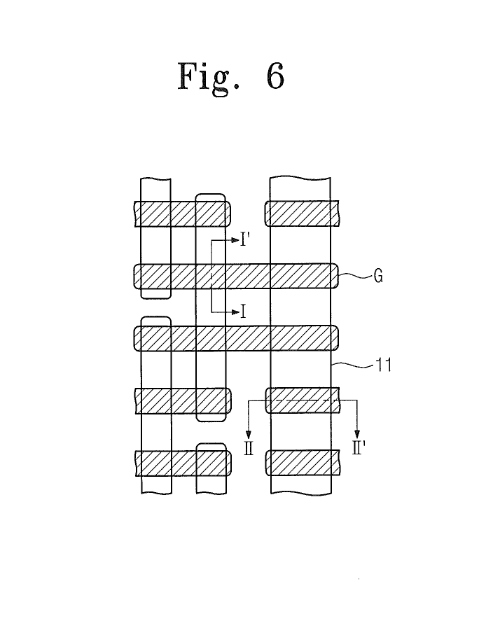

FIG. 6 is a plan view illustrating an example of a layout of a semiconductor device. Referring to FIG. 6, a semiconductor device includes an active area 11 formed at a substrate. A gate G may cross over the active region 11.

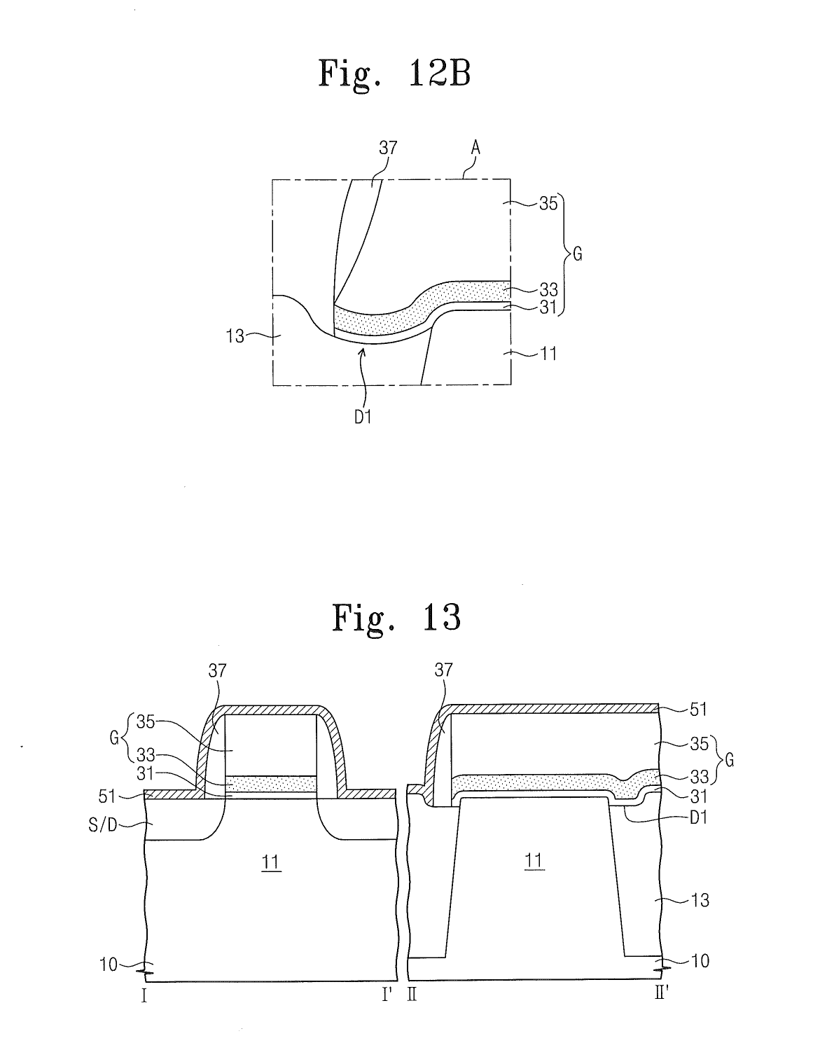

A method of forming a semiconductor device according to some embodiments will be described hereinafter. FIGS. 7 to 11, 12A, and 13 to 15 are cross-sectional views taken along lines I-I′ and II-II′ of FIG. 6 to illustrate a method of forming a semiconductor device according to some embodiments of the inventive concept. FIG. 12B is an enlarged view of a portion ‘A’ of FIG. 12A.

Referring to FIG. 7, a substrate 10 is provided. The substrate 10 may be a silicon substrate. The substrate 10 may further include one selected from a group consisting of a single-crystalline silicon layer, a silicon-on-insulator (SOI), and a silicon-germanium layer. The substrate 10 may be doped with dopants of a first conductivity type (e.g., a P-type).

A mask pattern 23 is formed on the substrate 10. The mask pattern 23 may include a silicon nitride layer. The silicon nitride layer may be formed by a chemical vapor deposition (CVD) process. A buffer oxide layer 21 may be formed between the mask pattern 23 and the substrate 10. For example, the buffer oxide layer 21 may be a thermal oxide layer.

The substrate 10 may be etched using the mask pattern 23 as an etch mask to form a trench 12. A device isolation insulating layer 13 is formed to fill the trench 12. The device isolation insulating layer 13 may include a silicon oxide layer. A liner nitride layer may be formed between an inner surface of the trench 12 and the device isolation insulating layer 13. Before the liner nitride layer is formed, a thermal oxide layer may be formed on the inner surface of the trench 12. The device isolation insulating layer 13 is planarized until the mask pattern 23 is exposed. The planarized device isolation insulating layer 13 fills the trench 12. The device isolation insulating layer 13 may be planarized by a chemical mechanical polishing (CMP) process. The planarized device isolation insulating layer 13 defines the active area 11. The active area 11 may be formed to have a planar structure including a flat top surface or a fin structure including a fin protruding from a flat surface.

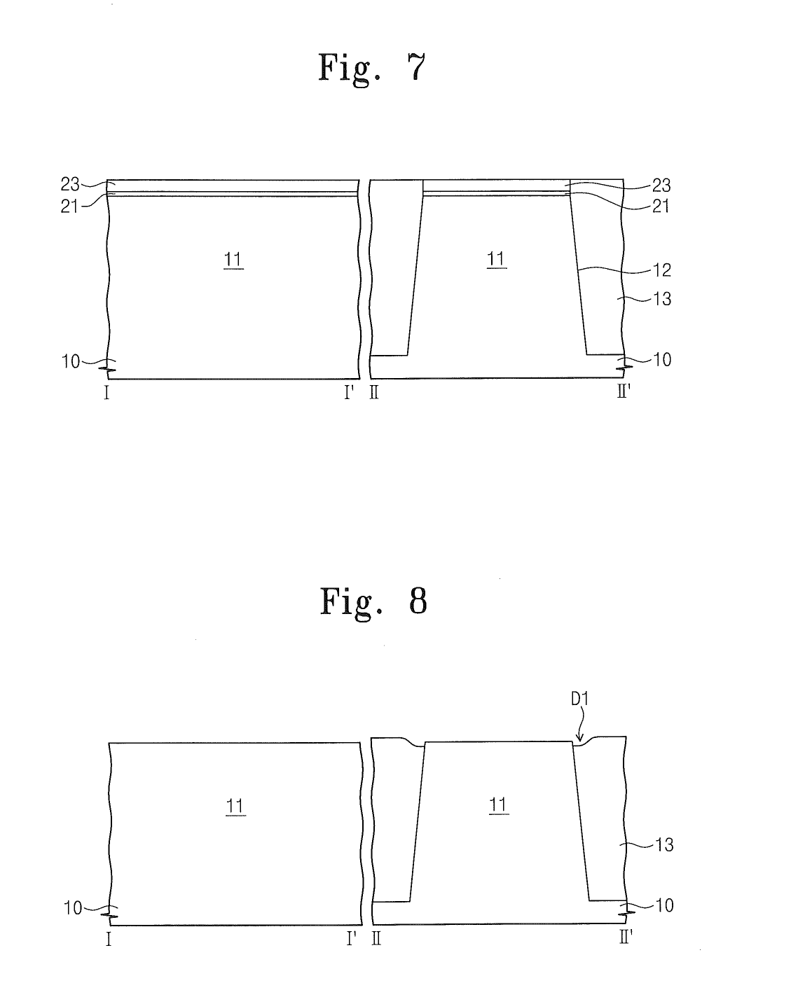

Referring to FIG. 8, the mask pattern 23 and the buffer oxide layer 21 are removed to expose the active area 11. The removal process of the mask pattern 23 and the buffer oxide layer 21 may be performed by a wet etching process. A portion of the device isolation insulating layer 13 may also be etched by the removal process of the mask pattern 23 and the buffer oxide layer 21. Particularly, an edge of the device isolation insulating layer 13 adjacent to the active area 11 may be further etched to form a dent D1. The dent D1 may be recessed to be lower than a top surface of the device isolation insulating layer 13. A bottom surface of the dent D1 may be lower than a top surface of the active area 11.

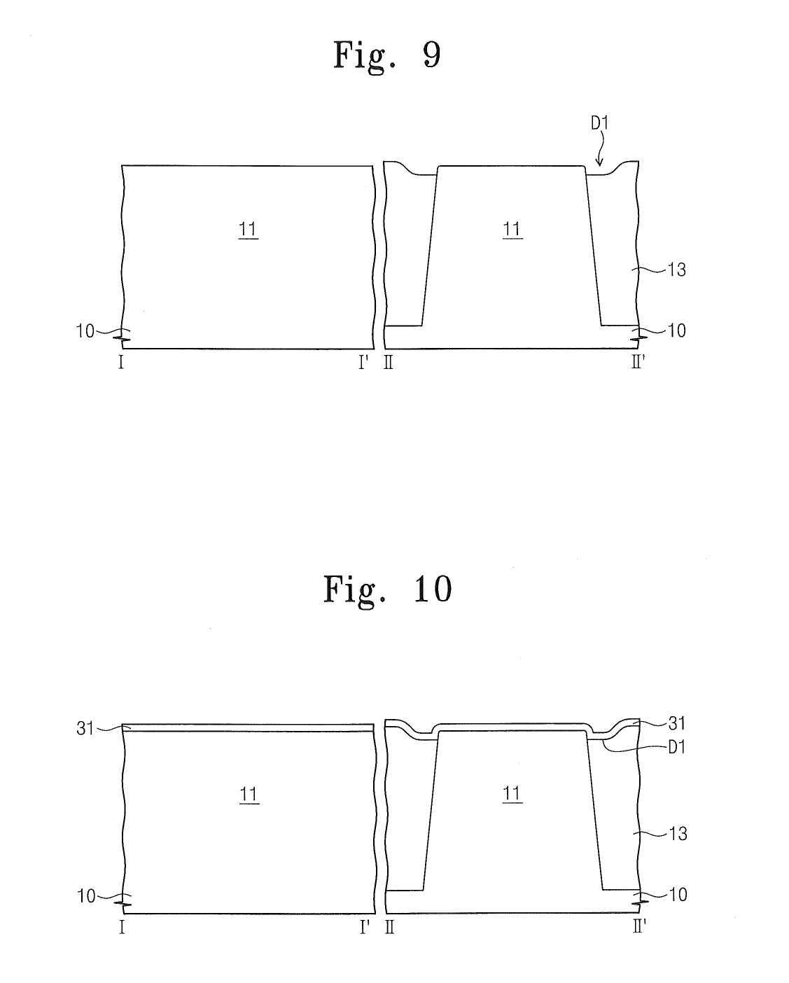

Referring to FIG. 9, since a natural oxide layer may be formed on a surface of the active region 11, a cleaning process may be performed for removing the natural oxide layer. The cleaning process for removing the natural oxide layer may be performed using a solution including, for example, hydrofluoric acid. In this case, the device isolation insulating layer 13 may be further etched to be recessed. Thus, the bottom surface of the dent D1 may be further lowered.

Referring to FIG. 10, a gate insulating layer 31 is formed. The gate insulating layer 31 may include at least one selected from a group consisting of an oxide, a nitride, an oxynitride, a metal silicate, and an insulating high-k refractory metal oxide (e.g., hafnium oxide and/or aluminum oxide). In an embodiment, the gate insulating layer 31 may include a refractory metal oxide layer, a refractory metal silicon oxide layer, and/or a refractory metal silicon oxynitride layer. For example, the gate insulating layer 31 may include a hafnium oxide layer, a hafnium silicon oxide layer, and/or a hafnium silicon oxynitride layer.

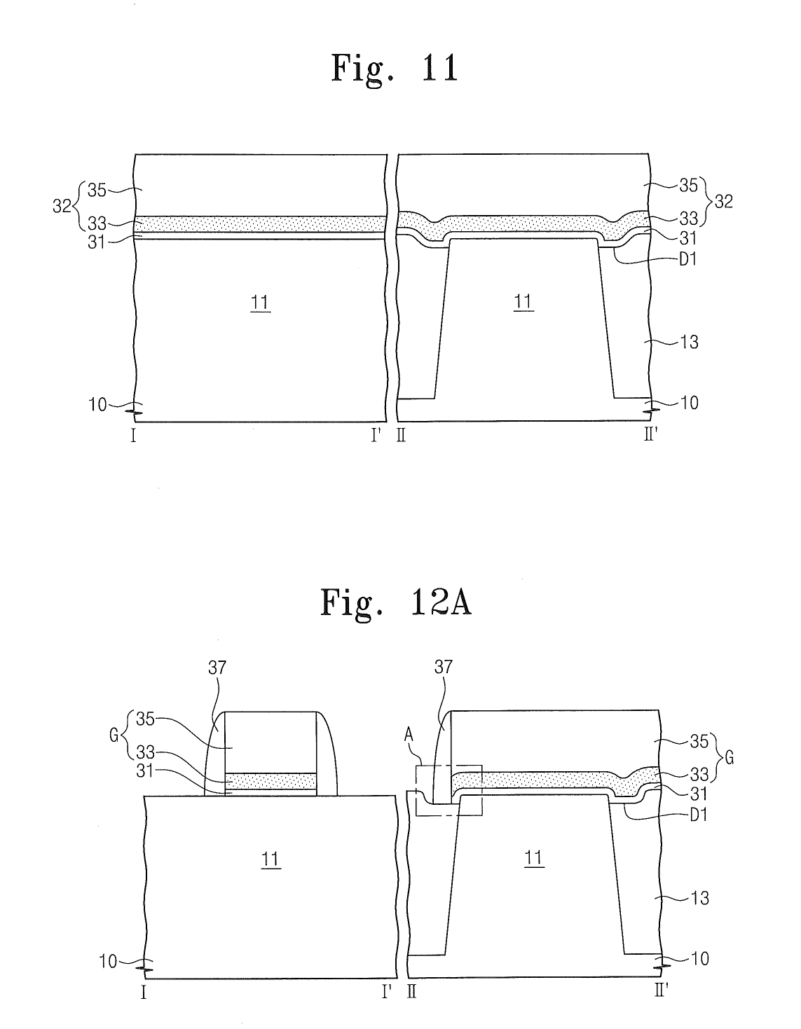

Referring to FIG. 11, a gate layer 32 is formed on the gate insulating layer 31. The gate layer 32 may include a first metal layer 33. The first metal layer 33 may include a metal nitride layer (e.g., a titanium nitride layer, a tungsten nitride layer, or a tantalum nitride layer). The first metal layer 33 may further include a tungsten layer or a molybdenum layer formed on the metal nitride layer. The gate layer 32 may further include a poly-silicon layer 35 on the first metal layer 33. The poly-silicon layer 35 may be doped with dopants. The first metal layer 33 and the poly-silicon layer 35 may be formed by a sputtering method. A thickness of the poly-silicon layer 35 may be greater than a thickness of the first metal layer 33.

Referring to FIG. 12A, the gate layer 32 is patterned to form a gate G. The buffer solution according to the inventive concept may be used for removing particles caused by the patterning of the gate layer 32. The buffer solution according to the inventive concept does not etch the first metal layer 33 of the gate G to any significant extent, if at all. An end portion of the gate G may extend over the dent D1. A sidewall spacer 37 covers a sidewall of the gate G. The sidewall spacer 37 may include a silicon oxide layer and/or a silicon nitride layer.

Particles may occur during the patterning process of the gate layer 32. The particles may be removed through a cleaning process. The buffer solution according to the inventive concept may effectively remove the particles but may not etch the first metal layer 33 of the gate G. As a result, the buffer solution according to the inventive concept is very effective in cleaning the substrate including the metal layer (particularly, the metal nitride layer).

Referring to FIG. 12B, a sidewall of the poly-silicon layer 35 may not be completely vertically etched by the patterning process of the gate layer 32, such that a lower portion of the poly-silicon layer 35 may extend over the device isolation insulating layer 13 adjacent thereto. A sidewall of the lower portion of the poly-silicon layer 35 may have a curvature concave toward the active area 11. This may be caused by the shape of the dent D1 and difference between etch rates of the poly-silicon layer 35 and the first metal layer 33 etched by successive processes. Additionally, a width of the first metal layer 33 disposed under the poly-silicon layer 35 may be greater than a width of the poly-silicon layer 35, and the first metal layer 33 may further extend over the device isolation insulating layer 13 (e.g., the dent D1). Thus, unlike as shown in FIG. 12A, the sidewall spacer 37 may not completely cover the gate G and may expose a portion (e.g., the first metal layer 33) of the gate G. Additionally, as semiconductor devices become more highly integrated, a length of the gate G may be reduced and a thickness of the sidewall spacer 37 may also be reduced. Thus, the sidewall spacer 37 may expose a portion of the first metal layer 33 of the gate G in the dent D1.

Referring to FIG. 13, dopant ions of a second conductivity type (e.g., a N-type) are injected into the active area 11 using the gate G as a mask, thereby forming source/drain regions S/D. A second metal layer 51 is provided on the active area 11 and the gate G. The second metal layer 51 may include nickel. The second metal layer 51 may further include platinum of about 1 wt % to about 15 wt %. The second metal layer 51 may have a thickness of about hundreds Å. A titanium nitride layer (not illustrated) may be additionally formed on the second metal layer 51.

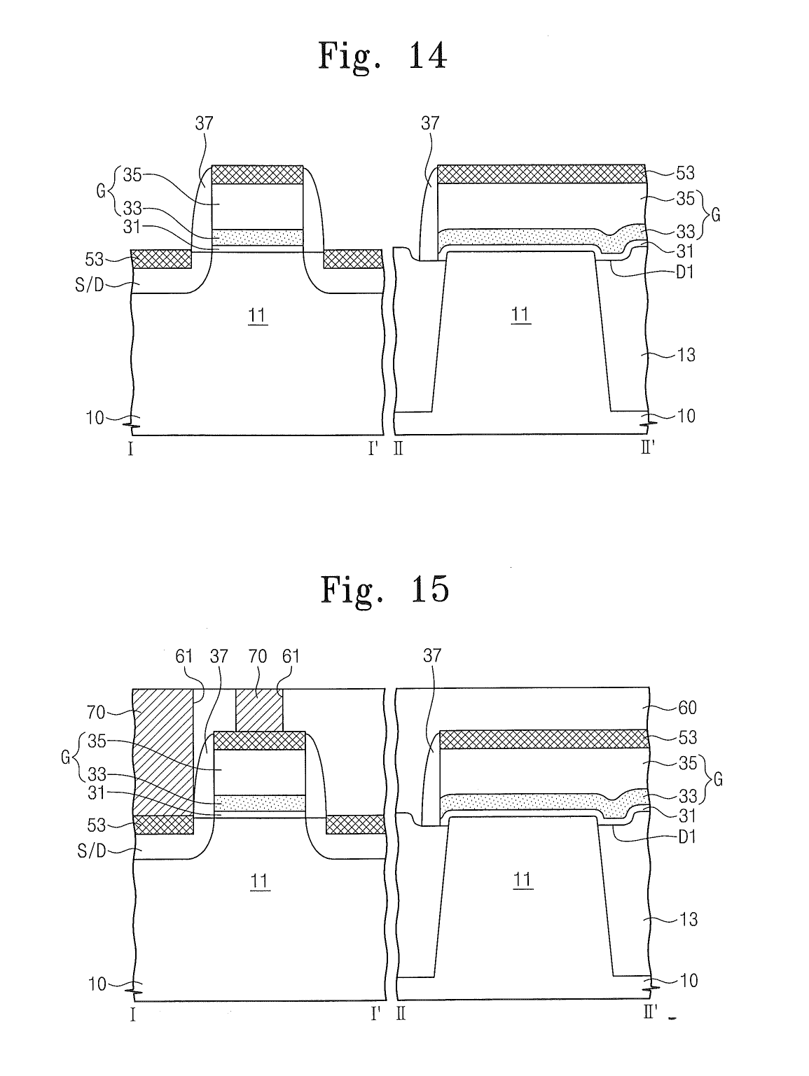

Referring to FIG. 14, a thermal treatment process is performed on the second metal layer 51 to form a first metal silicide layer 53. The second metal layer 51 may react with silicon of the substrate 10 and/or the poly-silicon layer 35 of the gate G to form the first metal silicide layer 53. The first metal silicide layer 53 may be formed on the gate G and the active area 11 (e.g., the source/drain regions S/D) disposed at both sides of the gate G, respectively. The thermal treatment process may include a first thermal treatment process and a second thermal treatment process performed after the first thermal treatment process. For example, the first thermal treatment process may be performed at a temperature of about 200 degrees Celsius to about 350 degrees Celsius. The first thermal treatment process may be a furnace thermal treatment process. Most of the second metal layer 51 may be converted into the first metal silicide layer 53 by the first thermal treatment process. However, a portion of the second metal layer 51 may remain in a form of a residue, which is unreacted with silicon. Since the unreacted metal residue results in a failure of a semiconductor device, it is advisable that it be removed. After the first thermal treatment process is performed, the unreacted metal residue may be removed using an electrolyzed sulfuric acid (ESA).

The second thermal treatment process is performed at a higher temperature than the first thermal treatment process. For example, the second thermal treatment process may be performed at a temperature of about 400 degrees Celsius or more. The first metal silicide layer 53 may be transformed into a mono silicide layer by the second thermal treatment process. The second thermal treatment process may be a laser thermal treatment process or a halogen-lamp thermal treatment process.

After the second thermal treatment process is performed, the unreacted metal residue may be additionally removed. For example, the electrolyzed sulfuric acid (ESA) or an aqua regia, e.g. nitro-hydrochloric acid, may be used for the additional removal process of the unreacted metal residue.

Particles may appear during the formation process of the first metal silicide layer 53. The particles may be removed through a cleaning process. As described with reference to FIG. 12B, the first metal layer 33 of the gate G may be exposed to be influenced by the cleaning process. The buffer solution according to the inventive concept may effectively remove the particles but may not etch the first metal layer 33 of the gate G. As a result, the buffer solution according to the inventive concept is effective in cleaning the substrate including the metal layer (particularly, the metal nitride layer).

Referring to FIG. 15, an interlayer insulating layer 60 is formed to cover the gate G and the first metal silicide layer 53. The interlayer insulating layer 60 may include a silicon oxide layer. The interlayer insulating layer 60 may be patterned to form first openings 61 exposing the first silicide layers 53 on the source/drain region S/D and gate G, respectively. Particles in the first openings 61 may be removed using the buffer solution according to the inventive concept. The buffer solution according to the inventive concept is effective in removing the particles in the first openings 61 but is generally ineffective in etching the metal layer which is formed under the interlayer insulating layer 60 but is not covered by the interlayer insulating layer 60. Contact plugs 70 may be formed in the first openings 61, respectively. The contact plugs 70 may include tungsten.

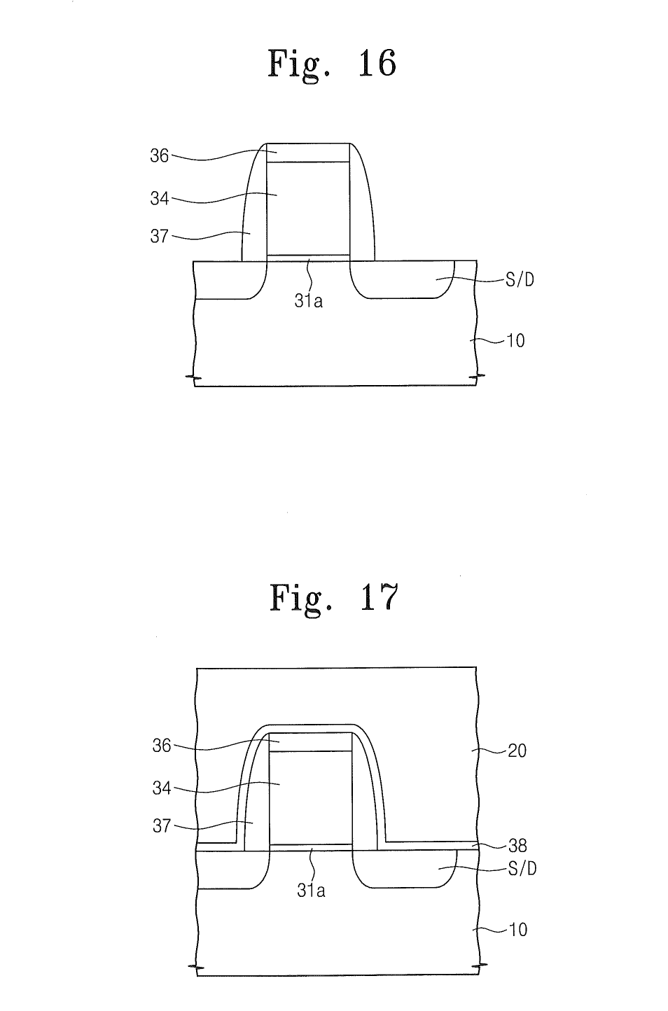

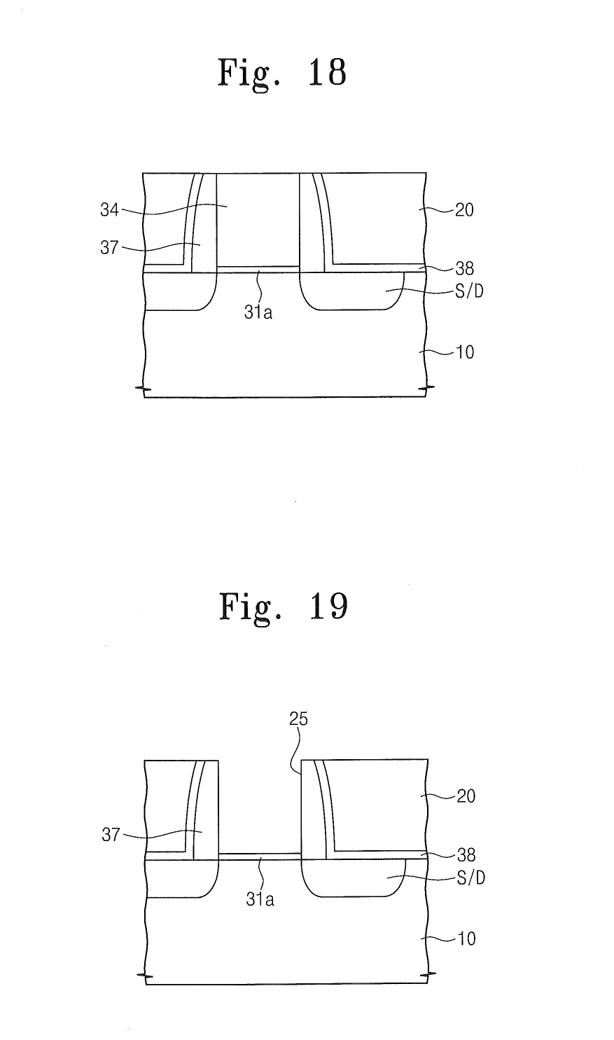

FIGS. 16 to 22 are cross-sectional views illustrating a method of forming a semiconductor device according to other embodiments of the inventive concept.

Referring to FIGS. 16 to 19, a mold insulating layer 20 having a gate trench 25 may be formed on a substrate 10. The mold insulating layer 20 may include, for example, a silicon oxide layer. A method of forming the mold insulating layer 20 having the gate trench 25 will be described as an example hereinafter.

Referring to FIG. 16, a first gate insulating layer 31a, a dummy gate 34, and a hard mask pattern 36 may be sequentially stacked on the substrate 10 described with reference to FIGS. 7 to 9. The first gate insulating layer 31a may include a silicon oxide layer. The dummy gate 34 may include a poly-silicon layer. The hard mask pattern 36 may include a silicon oxide layer and/or a silicon nitride layer. A sidewall spacer 37 may be formed on the sidewalls of the dummy gate 34 and the hard mask pattern 36. The sidewall spacer 37 may include a silicon oxide layer and/or a silicon nitride layer. Source/drain regions S/D may be formed in the substrate 10 at both sides of the dummy gate 34, respectively.

Referring to FIG. 17, a liner layer 38 may be formed to cover the substrate 10, the sidewall spacer 37, and the hard mask pattern 36. The liner layer 38 may include a silicon oxide layer and/or a silicon nitride layer. A mold insulating layer 20 may be formed on the liner layer 38.

Referring to FIGS. 17 and 18, a planarization process may be performed to expose the dummy gate 34. At this time, the mold insulating layer 20 is planarized and the hard mask pattern 36 is removed. The dummy gate 34 is selectively removed to form the mold insulating layer 20 having the gate trench 25. The first gate insulating layer 31a may be exposed by the gate trench 25. Particles caused by the planarization process may be removed by the buffer solution according to the inventive concept.

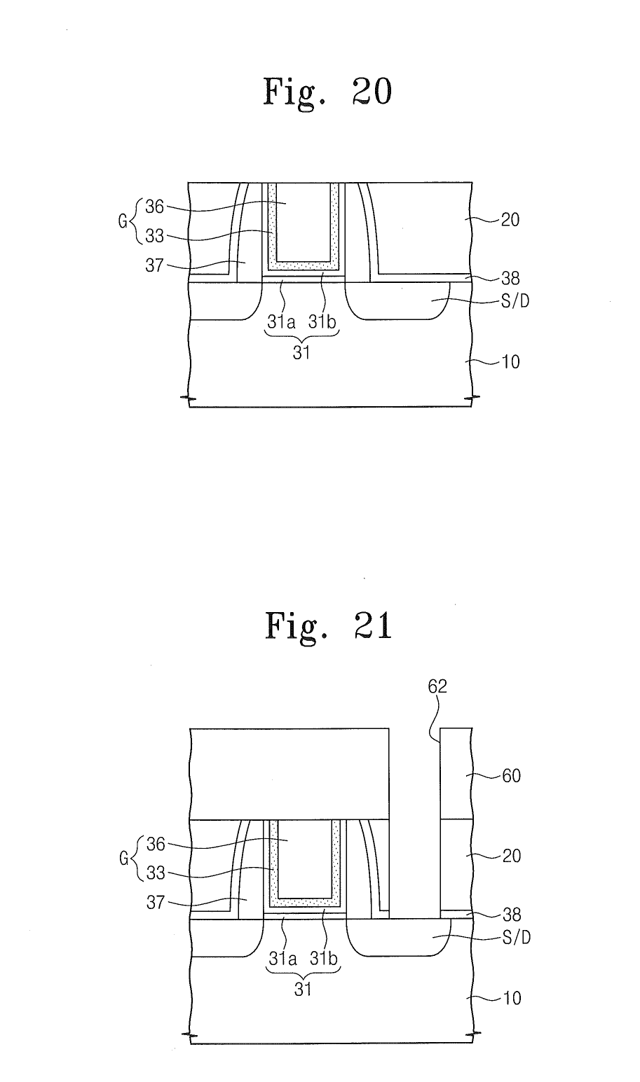

Referring to FIG. 20, a second gate insulating layer 31b is formed. The second gate insulating layer 31b may include at least one selected from a group consisting of silicon nitride, silicon oxynitride, a metal silicate, and an insulating high-k refractory metal oxide (e.g., hafnium oxide and/or aluminum oxide). In an embodiment, the second gate insulating layer 31b may include a refractory metal oxide layer, a refractory metal silicon oxide layer, and/or a refractory metal silicon oxynitride layer. For example, the second gate insulating layer 31b may include a hafnium oxide layer, a hafnium silicon oxide layer, and/or a hafnium metal silicon oxynitride layer. In an embodiment, the first gate insulating layer 31a may be removed before the second gate insulating layer 31b is formed. In another embodiment, a first gate insulating layer 31a may be newly formed by thermally treating the substrate 10 exposed by the gate trench 25. A gate insulating layer 31 may include the first gate insulating layer 31a and the second gate insulating layer 31b.

A gate G is formed on the gate insulating layer 31. A gate material may be deposited to fill at least a portion of the gate trench 25 and then may be planarized to expose the mold insulating layer 20, thereby forming the gate G. The gate G may include a metal nitride layer 33 and a third metal layer 36 which are sequentially stacked. The metal nitride layer 33 may include a titanium nitride layer and/or a tantalum nitride layer. The third metal layer 36 may include, for example, a titanium layer and an aluminum layer which are sequentially stacked. Particles caused by the planarization process of the gate material may be removed using the buffer solution according to the inventive concept. The buffer solution according to the inventive concept may effectively remove small-sized particles but may not etch the metal nitride layer 33 and the third metal layer 36 to any significant extent, if at all.

Referring to FIG. 21, an interlayer insulating layer 60 may be formed to cover the gate G. The interlayer insulating layer 60 may include a silicon oxide layer. The interlayer insulating layer 60 may be patterned to form a first opening 62 exposing the substrate 10 at a side of the gate G. Particles caused by the formation process of the first opening 62 may be removed using the buffer solution according to the inventive concept.

Referring to FIG. 22, a second metal silicide layer 55 is formed on the substrate 10 exposed by the opening 62. A contact plug 70 may be formed in the first opening 62. The contact plug 70 may include tungsten. In the present embodiment, the second metal silicide layer 55 is formed on one of a source and a drain. However, the inventive concept is not limited thereto. In another embodiment, the second metal silicide layers 55 may be formed on the source and the drain, respectively.

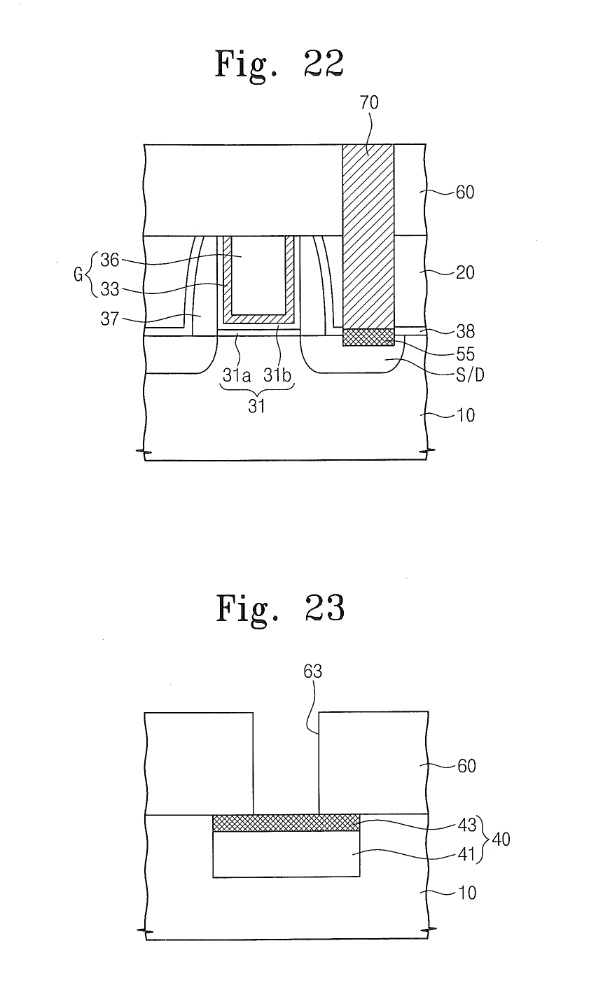

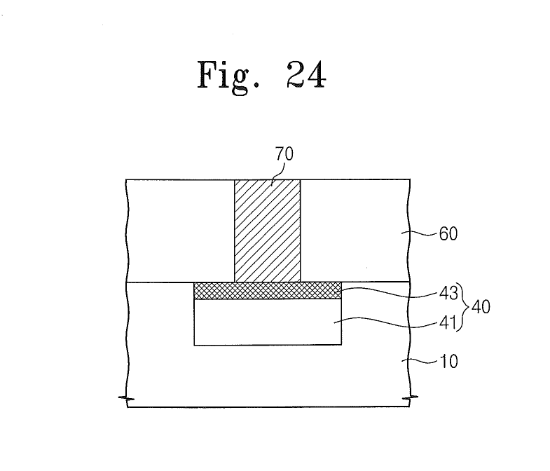

FIGS. 23 and 24 are cross-sectional views illustrating a method of forming a semiconductor device according to still other embodiments of the inventive concept.

Referring to FIG. 23, a conductive pattern 40 is provided. The conductive pattern 40 may be formed on or in a substrate 10. The conductive pattern 40 may include a first conductive pattern 41 and a second conductive pattern 43. The first conductive pattern 41 may be a metal pattern and the second conductive pattern 43 may be a metal nitride pattern. For example, the first conductive pattern 41 and the second conductive pattern 43 may include titanium and titanium nitride, respectively.

An interlayer insulating layer 60 is formed on the conductive pattern 40. The interlayer insulating layer 60 may be patterned to form a second opening 63 exposing the conductive pattern 40. Particles caused by the formation process of the second opening 63 may be removed using the buffer solution according to the inventive concept.

Referring to FIG. 24, a contact plug 70 may be formed in the second opening 63. The contact plug 70 may include tungsten.

The buffer solution according to the inventive concept is used in the cleaning processes described in the aforementioned embodiments. However, the inventive concept is not limited thereto. The buffer solution according to the inventive concept may be applied to various other cleaning processes of substrates including a metal layer (e.g., a metal nitride layer). The buffer solution according to the inventive concept may be effective in cleaning small sized particles but be ineffective in etching an exposed metal layer (particularly, a metal nitride layer) during the cleaning process to any significant extent, if at all. As a result, reliability of the semiconductor device may be more improved.

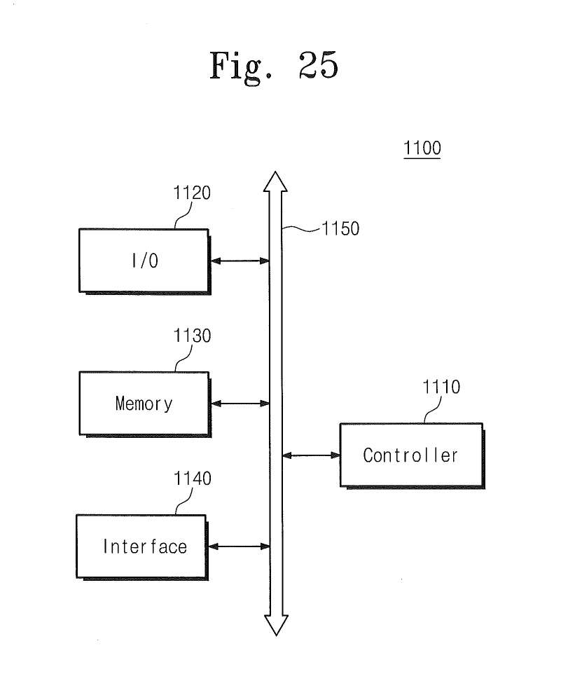

FIG. 25 is a schematic block diagram illustrating an example of electronic devices including semiconductor devices formed according to exemplary embodiments of the inventive concept.

Referring to FIG. 25, an electronic device 1100 according to exemplary embodiments may include a controller 1110, an input/output (I/O) unit 1120, a memory device 1130, an interface unit 1140 and a data bus 1150. At least two of the controller 1110, the I/O unit 1120, the memory device 1130 and the interface unit 1140 may communicate with each other through the data bus 1150. The data bus 1150 may correspond to a path through which electrical signals are transmitted.

The controller 1110 may include at least one of a microprocessor, a digital signal processor, a microcontroller or another logic device. The other logic device may have a similar function to any one of the microprocessor, the digital signal processor and the microcontroller. The I/O unit 1120 may include a keypad, a keyboard and/or a display unit. The memory device 1130 may store data and/or commands. The interface unit 1140 may transmit electrical data to a communication network or may receive electrical data from a communication network. The interface unit 1140 may operate by a wireless or cable communication. For example, the interface unit 1140 may include an antenna for wireless communication or a transceiver for cable communication. Although not shown in the drawings, the electronic device 1100 may further include a fast DRAM device and/or a fast SRAM device which acts as a cache memory for improving an operation of the controller 1110.

The electronic device 1100 may be applied to a personal digital assistant (PDA), a portable computer, a web tablet, a wireless phone, a mobile phone, a digital music player, a memory card or other electronic products.

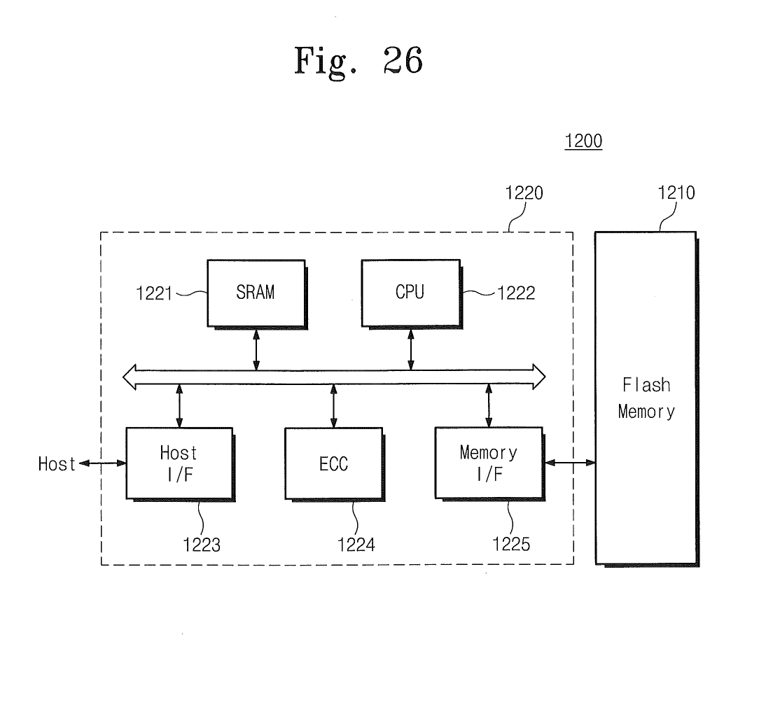

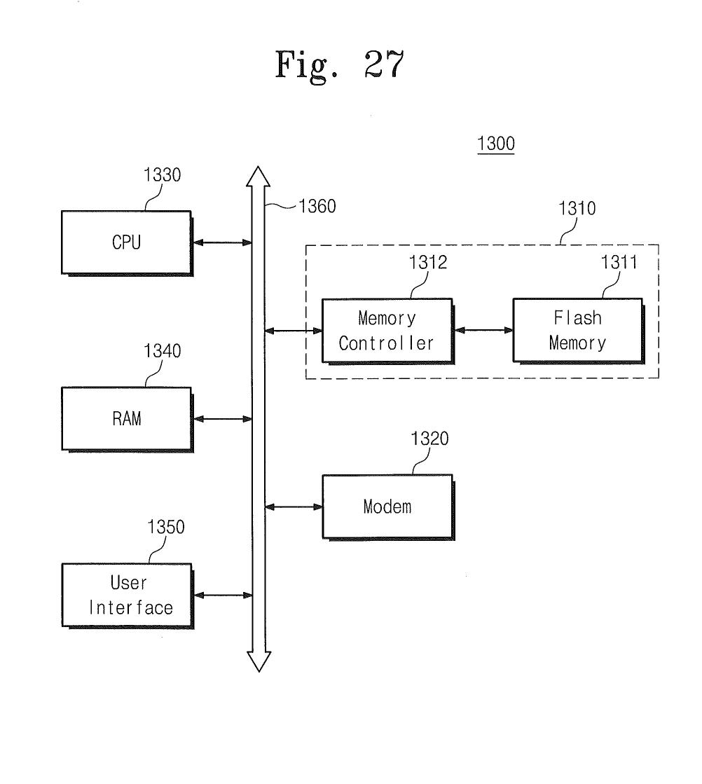

FIG. 26 is a schematic block diagram illustrating an example of memory cards including semiconductor devices formed according to exemplary embodiments of the inventive concept.

Referring to FIG. 26, a memory card 1200 includes a memory device 1210. The memory card 1200 may include a memory controller 1220 that controls data communication between a host and the memory device 1210.

The memory controller 1220 may include a central processing unit (CPU) 1222 that controls overall operations of the memory card 1200. In addition, the memory controller 1220 may include an SRAM device 1221 used as an operation memory of the CPU 1222. Moreover, the memory controller 1220 may further include a host interface unit 1223 and a memory interface unit 1225. The host interface unit 1223 may be configured to include a data communication protocol between the memory card 1200 and the host. The memory interface unit 1225 may connect the memory controller 1220 to the memory device 1210. The memory controller 1220 may further include an error check and correction (ECC) block 1224. The ECC block 1224 may detect and correct errors of data which are read out from the memory device 1210. Even though not shown in the drawings, the memory card 1200 may further include a read only memory (ROM) device that stores code data to interface with the host. The memory card 1200 may be used as a portable data storage card. Alternatively, the memory card 1200 may be realized as solid state disks (SSD) which are used as hard disks of computer systems.

FIG. 27 is a schematic block diagram illustrating an example of information processing systems including semiconductor devices formed according to exemplary embodiments of the inventive concept.

Referring to FIG. 27, at least one of the semiconductor devices formed in the aforementioned embodiments may be installed in a memory system 1310, and the memory system 1310 may be installed in an information processing system 1300. The information processing system 1300 according to exemplary embodiments may include a modem 1320, a central processing unit (CPU) 1330, a RAM 1340, and a user interface unit 1350, which may be electrically connected to the memory system 1310 through a system bus 1360. The memory system 1310 may include a memory device 1311 and a memory controller 1312 controlling an overall operation of the memory device 1311. Data processed by the CPU 1330 and/or inputted from an external system may be stored in the memory system 1310. The memory system 1310 may be provided as a solid state drive SSD. In this case, the information processing system 1300 may be able to store reliably a large amount of data in the memory system 1310. This increase in reliability enables the memory system 1310 to conserve resources for error correction, such that a high speed data exchange function may be provided to the information processing system 1300. Although not shown in the drawings, the information processing system 1300 may further include an application chipset, a camera image processor (CIS), and/or an input/output device.

The semiconductor devices and the memory systems according to the inventive concept may be encapsulated using various packaging techniques. For example, the semiconductor devices and the memory systems may be encapsulated using any one of a package on package (POP) technique, a ball grid arrays (BGAs) technique, a chip scale packages (CSPs) technique, a plastic leaded chip carrier (PLCC) technique, a plastic dual in-line package (PDIP) technique, a die in waffle pack technique, a die in wafer form technique, a chip on board (COB) technique, a ceramic dual in-line package (CERDIP) technique, a plastic metric quad flat package (PMQFP) technique, a plastic quad flat package (PQFP) technique, a small outline package (SOIC) technique, a shrink small outline package (SSOP) technique, a thin small outline package (TSOP) technique, a thin quad flat package (TQFP) technique, a system in package (SIP) technique, a multi chip package (MCP) technique, a wafer-level fabricated package (WFP) technique and a wafer-level processed stack package (WSP) technique.

According to exemplary embodiments of the inventive concept, the small sized particles may be effectively removed but the metal layer (particularly, the metal nitride layer) may not be etched to any significant extent, if at all.

While the inventive concept has been described with reference to example embodiments, it will be apparent to those skilled in the art that various changes and modifications may be made without departing from the spirit and scope of the inventive concept. Therefore, it should be understood that the above embodiments are not limiting, but illustrative. Thus, the scope of the inventive concept is to be determined by the broadest permissible interpretation of the following claims and their equivalents, and shall not be restricted or limited by the foregoing description.

What is claimed is:

1. A method of treating a substrate comprising applying a buffer solution including carbon dioxide (CO₂) water combined with an alkaline solution to treat the substrate.

2. The method of claim 1, wherein the alkaline solution is formed by electrolyzing water.

3. The method of claim 2, wherein electrolyzing the water comprises separating hydrogen from the water.

4. The method of claim 1, wherein the alkaline solution includes NH₄OH or tetramethyl ammonium hydroxide (TMAH).

5. The method of claim 1, wherein the buffer solution does not substantially include hydrogen peroxide.

6. The method of claim 1, wherein the substrate includes a metal layer formed thereon.

7. The method of claim 1, wherein application of the buffer solution and alkaline solution results in removal of particles from the substrate.

8. The method of claim 7, wherein application of the buffer solution and alkaline solution further comprises etching a silicon layer on the substrate.

9. A method of forming a semiconductor device comprising:
forming a metal layer on a substrate; and
treating the substrate with a buffer solution including carbon dioxide (CO₂) water combined with an alkaline solution.

10. The method of claim 9, wherein the alkaline solution is formed by electrolyzing water.

11. The method of claim 9, wherein the alkaline solution includes NH₄OH or tetramethyl ammonium hydroxide (TMAH).

12. The method of claim 9, wherein the metal layer includes a metal nitride layer.

13. The method of claim 12, further comprising:
forming a gate insulating layer on the substrate; and
forming a metal gate including the metal layer on the gate insulating layer,
wherein the gate insulating layer includes a metal oxide layer, a metal silicon oxide layer, and/or a metal silicon oxynitride layer.

14. The method of claim 13, wherein the gate insulating layer comprises a hafnium oxide layer, a hafnium silicon oxide layer, a hafnium oxynitride layer, or a combination thereof.

15. The method of claim 13, further comprising forming a gate layer on the gate insulating layer, wherein the gate layer comprises a metal layer.

16. The method of claim 15, further comprising forming a second metal layer on a polysilicon layer disposed on the metal layer.

17. The method of claim 16, wherein a thermal treatment is performed on the second metal layer to form a metal silicide layer.

18. The method of claim 15, wherein the buffer solution and alkaline solution removes particles from the substrate but does not etch the metal layer.

19. A substrate treating apparatus comprising:
a first cleaning solution supply unit providing an alkaline solution;
a second cleaning solution supply unit providing carbon dioxide (CO₂) water;
a cleaning solution mixing unit connected to the first and second cleaning solution supply units, the cleaning solution mixing unit combining the alkaline solution with the CO₂ water to form a buffer solution; and
a spray unit spraying the buffer solution.

20. The substrate treating apparatus of claim 19, wherein the first cleaning solution supply unit electrolyzes water.
